(19) United States
(12) Patent Application Publication
(10) Pub. No.: US 2026/0044942 A1
(43) Pub. Date: Feb. 12, 2026

(54) METHOD AND APPARATUS FOR PERFORMING DIFFUSION-BASED IMAGE PROCESSING USING TIERED SAMPLING STEP SHARING

(71) Applicant: CANON MEDICAL SYSTEMS CORPORATION, Tochigi (JP)

(72) Inventors: Tzu-Cheng LEE, Vernon Hills, IL (US); Xi CHEN, Vernon Hills, IL (US); Liang CAI, Vernon Hills, IL (US)

(73) Assignee: CANON MEDICAL SYSTEMS CORPORATION, Tochigi (JP)

(21) Appl. No.: 19/291,207

(22) Filed: Aug. 5, 2025

Related U.S. Application Data
(63) Continuation-in-part of application No. 18/796,076, filed on Aug. 6, 2024.
(60) Provisional application No. 63/679,756, filed on Aug. 6, 2024.

(51) Int. Cl. G06T 5/70; G01R 33/56; G06T 5/50

(52) U.S. Cl. CPC G06T 5/70; G01R 33/5608; G06T 5/50

(57) ABSTRACT

A method and apparatus for performing diffusion-based image processing are described. The method includes: obtaining a DDPM trained to restore a target image from noise over T sampling steps; dividing the T sampling steps into M tiers; and processing the plurality of input images in a tier-by-tier manner using the obtained DDPM, to generate a plurality of processed images. In each tier of a first M−1 tiers, the processing further comprises: grouping the plurality of input images into one or more groups, and over a sampling step within the tier, for each group, performing shared diffusion-based image processing on a representative image of the group, so as to generate a representative intermediate image, which is used as a starting point in a subsequent tier. In a last tier of the M tiers, the processing further comprises: over a sampling step, performing diffusion-based image processing independently with respect to each image.

### CROSS-REFERENCE TO RELATED APPLICATIONS

The present application is a continuation-in-part application of U.S. application Ser. No. 18/796,076, entitled “FAST DIFFUSION-BASED IMAGE RESTORATION WORKFLOW VIA SHARING OF INITIAL DIFFUSION STEPS,” filed on Aug. 6, 2024; claims the priority of U.S. Provisional Application No. 63/679,756, entitled “METHOD AND APPARATUS FOR PERFORMING DIFFUSION-BASED IMAGE RESTORATION USING TIERED SAMPLING STEP SHARING,” filed on Aug. 6, 2024; and is related to U.S. application Ser. No. 18/403,170, published as US20250217940A1, entitled “FAST DIFFUSION-BASED IMAGE RESTORATION WORKFLOW VIA SHARING OF INITIAL DIFFUSION STEPS,” filed on Jan. 3, 2024. The contents of all of the above patent applications are incorporated herein by reference in their entireties.

### BACKGROUND

### Field

The present disclosure relates to diffusion-based image processing of multiple images. More specifically, this disclosure relates to a method and apparatus that performs efficient processing of a plurality of images based on a denoising diffusion probabilistic model, through a tiered sampling step sharing workflow.

### Description of the Related Art

The background description provided herein is for the purpose of generally presenting the context of the disclosure. Work of the presently named inventors, to the extent the work is described in this background section, as well as aspects of the description that may not otherwise qualify as prior art at the time of filing, are neither expressly nor impliedly admitted as prior art against the present disclosure.

Deep learning-based image restoration, such as denoising, deblurring, super-resolution, and compressed sensing, are important applications in medical imaging. The goal of these techniques is to recover high-quality images from potentially noisy measurements given through a known or learned degradation model. For most real-world medical imaging applications, the restoration process is performed using end-to-end supervised neural networks trained on paired datasets of high-quality and degraded images. However, these approaches often result in suboptimal diagnostic value due to over-smoothing or the lack of high-fidelity details.

Generative model approaches, on the other hand, have demonstrated the ability to learn complex empirical distributions of images. Methods such as Variational Autoencoders (VAEs) and Generative Adversarial Networks (GANs) have shown promising results in producing visually convincing images. However, these approaches often suffer from various limitations. For example, VAEs often yield sub-optimal sample quality, while GANs require carefully designed regularization and optimization strategies to mitigate issues such as optimization instability and mode collapse.

Diffusion-based models, such as Denoising Diffusion Probabilistic Models (DDPMs), are a class of generative models that learn to match a data distribution by reversing a gradual multi-step noising process. It has shown that this class of models can outperform other deep learning-based generative approaches in terms of image quality. Recent studies have also demonstrated their potential in medical image restoration tasks.

Typically, DDPMs are computationally intensive, despite their advantages in image quality. Accordingly, inference time is usually a biggest hurdle for applying these techniques in clinical workflows. For example, a DDPM model with 1,000 diffusion steps requires 999 additional inference steps compared to conventional neural networks, significantly increasing the processing time and computational cost.

Therefore, it is desirable to reduce the inference time of diffusion-based image processing methods, while preserving the high quality of the restored images.

### SUMMARY

The present disclosure relates to a method of denoising images, including obtaining a diffusion-based probabilistic model that was trained, using at least one target image and at least one conditional image, to perform denoising over T steps, wherein T is an integer greater than or equal to two; obtaining a start image; determining a shared phase representative image based on a plurality of phase images; generating a sequence of representative images by performing a first sequence of T1 denoising sampling steps using the obtained model starting with the start image and the shared phase representative image as initial first sequence inputs; determining, from the generated sequence of representative images, an intermediate image; and for each phase image in the plurality of phase images: generating a corresponding sequence of restored images by performing a second sequence of T2 denoising sampling steps using the obtained model with the intermediate image and the input image as initial second sequence inputs; and determining a corresponding final restored image for each phase image based on the generated corresponding sequence of restored images, wherein T1 and T2 are integers greater than or equal to 1.

The disclosure additionally relates to a method for performing diffusion-based image processing on a plurality of input images. The method includes: obtaining a diffusion-based probabilistic model (DDPM) that was trained to restore a target image from noise over T sampling steps, wherein T is an integer greater than or equal to 3; dividing the T sampling steps into M tiers, wherein M is an integer greater than or equal to 3; and processing the plurality of input images in a tier-by-tier manner using the obtained DDPM, to generate a plurality of processed images. In each tier of a first M−1 tiers, the processing further comprises: grouping the plurality of input images into one or more groups, and over a sampling step within the tier, for each group of the one or more groups, performing shared diffusion-based image processing on a representative image of the group, so as to generate a representative intermediate image, which is used as a starting point for the diffusion-based image processing in a subsequent tier. In a last tier of the M tiers, the processing further comprises: over a sampling step within the last tier, performing diffusion-based image processing independently with respect to each image of the plurality of input images, without sharing.

Note that this summary section does not specify every embodiment and/or incrementally novel aspect of the present disclosure or claimed invention. Instead, the summary only provides a preliminary discussion of different embodiments and corresponding points of novelty. For additional details and/or possible perspectives of the invention and embodiments, the reader is directed to the Detailed Description section and corresponding figures of the present disclosure as further discussed below.

### BRIEF DESCRIPTION OF THE DRAWINGS

Various embodiments of this disclosure that are proposed as examples will be described in detail with reference to the following figures, wherein like numerals reference like elements, and wherein:

FIG. 1A shows an exemplary training process of a standard denoising diffusion probabilistic model (DDPM);

FIG. 1B shows an exemplary sampling (inference) process of a standard DDPM;

FIG. 1C shows an exemplary scenario in which a conditional image is applied as guide in both the training and inference processes of a standard DDPM;

FIG. 2A shows independent sampling processes performed on a series of 24 images acquired in sequence over a spatial or temporal direction;

FIG. 2B shows a schematic of a process for denoising a series of (N+1) images via a trained DDPM;

FIG. 3A shows a sharing mechanism performed on a series of 24 images acquired in sequence over a spatial or temporal direction, where a number (e.g., 4) of groups are implemented for initial sampling step sharing, followed by independent denoising processing;

FIG. 3B shows a schematic of an exemplary process for denoising a series of (N+1) images via a trained DDPM, using sharing of initial diffusion steps;

FIG. 4 shows a reverse denoising process in which a diffusion model restores an image by reversing noise from x_{T} (pure noise) to a final output image x₀;

FIG. 5 shows a tiered sharing mechanism performed on a series of 24 images acquired in sequence over a spatial or temporal direction, where a number (e.g., 3) of tiers are implemented for sampling step sharing, followed by independent denoising processing, in accordance with one embodiment of the present disclosure;

FIGS. 6A and 6B show schematics of a process for denoising a series of images via a trained DDPM, wherein tiered sharing of diffusion steps is implemented during inference, without conditional image guide (FIG. 6A), and with conditional image guide (FIG. 6B), in accordance with one embodiment of the present disclosure;

FIG. 7 shows a comparison of the structural similarity index (SSIM) across a 1022-slice image stack for two different sampling step sharing approaches;

FIG. 8 is a schematic of a hardware system for performing a method according to one embodiment of the present disclosure;

FIG. 9 is a schematic of an imaging system according to one embodiment of the present disclosure;

FIG. 10A is a schematic of a diffusion-based image restoration workflow according to one embodiment of the disclosure of U.S. application Ser. No. 18/796,076;

FIG. 10B is a schematic of a process for denoising a series of multiphasic images using a trained DDPM according to one embodiment of the disclosure of U.S. application Ser. No. 18/796,076;

FIG. 11 is a schematic of the multiphasic imaging diffusion-based denoising method according to one embodiment of the disclosure of U.S. application Ser. No. 18/796,076;

FIG. 12 shows a non-limiting example of a flow chart for a method of joint multiphasic imaging diffusion-based denoising according to one embodiment of the disclosure of U.S. application Ser. No. 18/796,076;

FIG. 13 is a schematic of automatically determining the shared sampling step number according to one embodiment of the disclosure of U.S. application Ser. No. 18/796,076; and

FIG. 14 illustrates the results of the joint multiphasic imaging diffusion-based denoising according to one embodiment of the disclosure of U.S. application Ser. No. 18/796,076.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For example, the order of discussion of the different steps as described herein has been presented for the sake of clarity. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

Referring now to the drawings, wherein like reference numerals designate identical or corresponding parts throughout the several views.

Furthermore, as used herein, the words “a,” “an,” and the like generally carry a meaning of “one or more,” unless stated otherwise. The term “plurality,” as used herein, is defined as two or more than two. The term “another,” as used herein, is defined as at least a second or more. The terms “including” and/or “having,” as used herein, are defined as comprising (i.e., open language). Reference throughout this document to “one embodiment,” “certain embodiments,” “an embodiment,” “an implementation,” “an example,” or similar terms means that a particular feature, structure, or characteristic described in connection with the embodiment is included in at least one embodiment of the present application. Thus, the appearances of such phrases or in various places throughout this specification are not necessarily all referring to the same embodiment. Furthermore, the particular features, structures, or characteristics may be combined in any suitable manner in one or more embodiments without limitation.

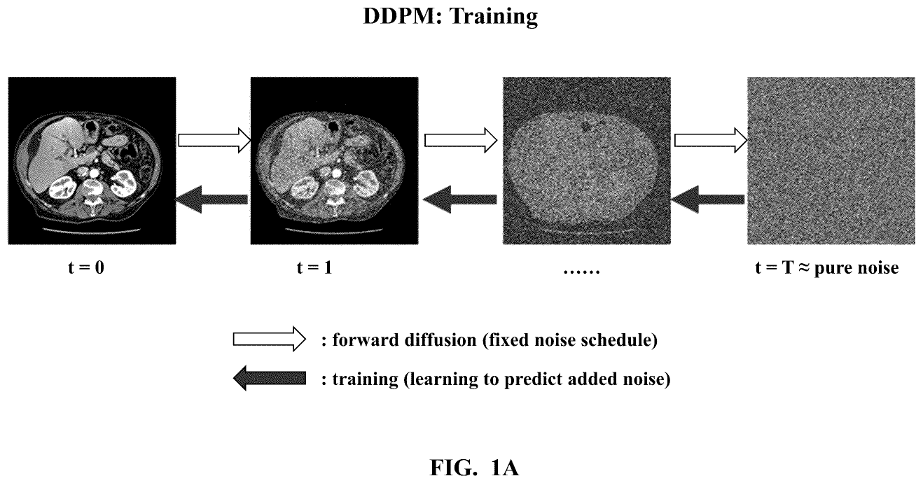

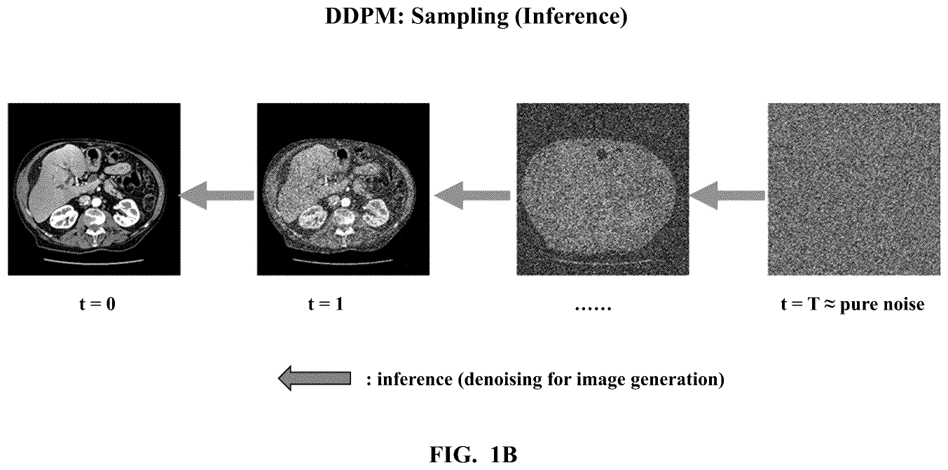

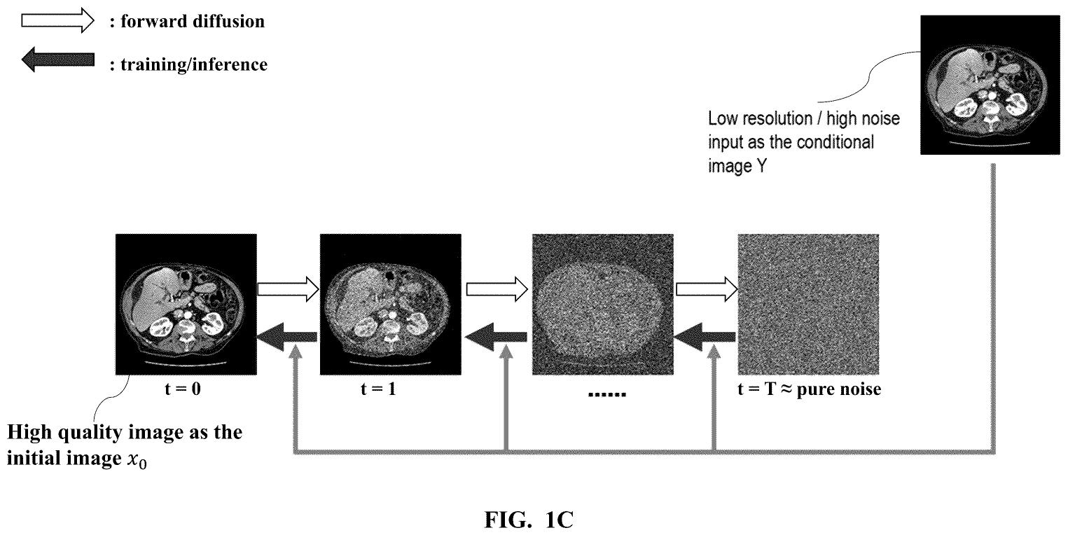

As discussed above, Denoising Diffusion Probabilistic Models (DDPMs) are a class of generative models that learn to reverse a gradual noising process in order to recover high-quality images from random noise. FIG. 1 shows an exemplary training process of a standard DDPM. In this process, a clean target image x₀(e.g., a CT image) is gradually corrupted through a forward diffusion process to obtain noisy images xₜ at a plurality of time steps t. At the final step t=T, the image is transformed into nearly pure Gaussian noise. The goal of the training process is to learn a noise prediction model ∈_{θ}(xₜ, t) that accurately estimates the added noise from a given noisy image xₜ and the corresponding time step t.

In the training process illustrated in Algorithm 1,

Algorithm 1 Training

| | |
|---|---|
| 1: | repeat |
| 2: | x₀ ~ q(x₀) |
| 3: | t ~ Uniform({1,...,T}) |
| 4: | ϵ ~ [symbol] (0, I) |
| 5: | Take gradient descent step on |
| | ∇_{θ} ∥ϵ − ϵ_{θ}(\sqrt{α̅ₜ}x₀ + |
| | \sqrt{1 − α̅ₜ}ϵ, t)∥² |
| 6: | until converged, |

θ represents the trainable parameters of the model, and αₜ, α̅ₜ are parameters of the fixed noise schedule used in the forward diffusion process. Typically, the training process includes repeatedly sampling a clean image x₀, selecting a random diffusion step t∈{1, . . . , T}, and sampling a noise vector ∈˜ [symbol] (0, I). The input to the neural network to be trained includes the noisy image xₜ (=\sqrt{α̅ᵢ}x₀+\sqrt{1−α̅ₜ}∈,t))) and the diffusion step t (which can represent a time index or a variance level). Optionally, a conditional image Y can be included as an additional input, which will be further described with reference to FIG. 1C. The training target is to minimize the difference between the actual noise E and the predicted noise ∈_{θ}(xₜ, t), as shown by the loss function in Algorithm 1.

Through this training process, the neural network can learn to estimate the noise added at each step, enabling it to reverse the diffusion process and recover a clean image from random noise. Once the training is complete, image generation or restoration can be carried out by starting from pure noise x_{T}, and sequentially applying the trained neural network to obtain x_{T-1}, x_{T-2}, . . . , x₀.

FIG. 1B shows an exemplary inference (also referred to as “sampling”) process of a standard DDPM. The inference process begins with a pure noise image x_{T}, which is sequentially denoised through a series of reverse diffusion steps, until a final restored image x₀ is obtained.

In the sampling process illustrated in Algorithm 2,

Algorithm 2 Sampling

1: X_{T}~ [symbol] (0, I)
2: for t = T, . . . , 1 do
3: z~ [symbol] (0, I) if t > 1, else z = 0
$4 : {x}_{t - 1} = \frac{1}{\sqrt{{α}_{t}}} ( {x}_{t} - \frac{1 - {α}_{t}}{\sqrt{1 - {\overline{α}}_{t}}} {ϵ}_{θ} ( {x}_{t} , t ) ) + {σ}_{t} z$
5: end for
6: return x₀,

αₜ, α̅ₜ, σₜ are predefined noise scheduling parameters. At each time step t, the trained neural network Ee receives, as input, the current noisy image xₜ and the corresponding diffusion step t. Although not shown in FIG. 1B, a conditional image Y can be optionally included to guide the inference process. The trained neural network Ee estimates the noise, which can be used to generate the denoised image xₜ₋₁ for the next step. This reverse process is repeated iteratively until t=0, generating the final output image x₀.

Guided DDPM frameworks are commonly used for image restoration applications. In this setting, a conditional image Y is provided as an auxiliary input to the neural network during the training and inference processes, enabling guided reverse sampling. FIG. 1C illustrates an exemplary use of a conditional image in both training and inference. As illustrated, the conditional image Y can be fed into the neural network alongside the noisy image xₜ and the diffusion step t, and influences the noise estimation at each iteration.

For example, when the model is trained using a high quality CT image as an initial image x₀, the conditional image Y can be a low-resolution, high-noise CT image. This guide allows the DDPM to effectively restore a specific desired output, rather than generate an arbitrary image from random noise.

As discussed previously, a major practical limitation of DDPMs is the high computational time. Since the DDPM restores the image through a gradual reverse diffusion process, it requires repeatedly applying the trained neural network over hundreds or even thousands of diffusion steps, making it significantly slower than a supervised-learning counterpart.

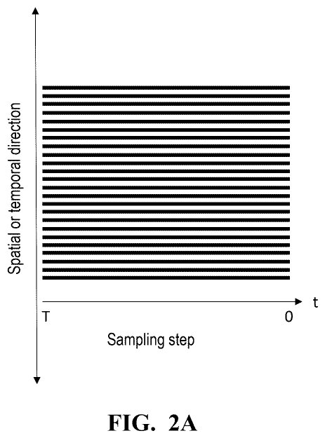

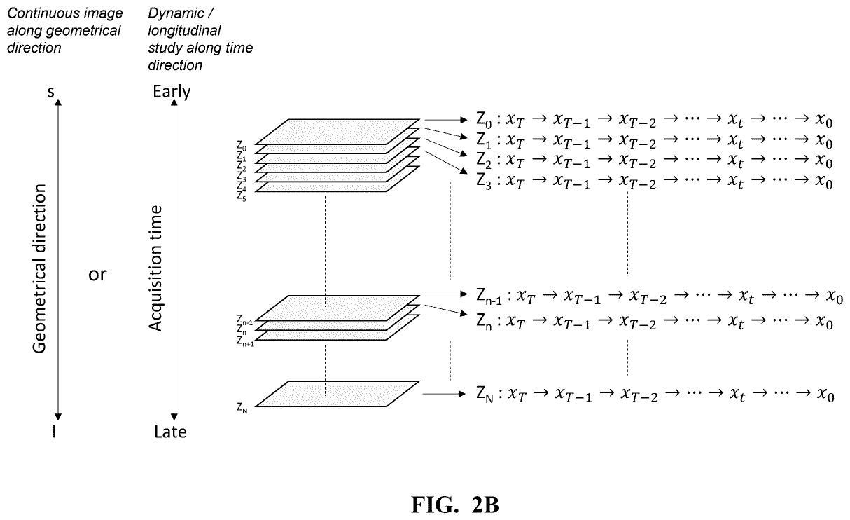

The computational burden becomes particularly problematic when applying DDPM to a sequence of images, such as continuous slices (e.g., in 3D imaging) along a geometrical direction or sequentially acquired images (e.g., in dynamic or longitudinal studies) along a temporal direction. FIG. 2A shows a conventional implementation in which each image in a sequence (e.g., 24 images in a spatial or temporal direction) is independently processed through a series of sampling steps. In this implementation, the total computational load grows linearly with the number of images and the number of diffusion steps. FIG. 2B provides a schematic of such conventional independent processing. A batch of (N+1) images Z₀, Z₁, . . . , Z_{N} are each restored by applying the trained diffusion model independently. Each image starts from a noisy image x_{T} and undergoes a series of denoising steps to yield a final output x₀, requiring inference through every time step T−1, T−2, . . . , 0.

Several acceleration techniques have been proposed to reduce the processing time of diffusion-based methods for image restoration. These methods include denoising diffusion implicit models (DDIMs), improved DDPMs that reduce the number of sampling steps in inference, early stopping, DPM solvers based on a fast ordinary differential equation (ODE) solver, pre-segmentation diffusion sampling that uses prior information for skipping reverse diffusion steps, high-frequency space diffusion models that operates on selected data for faster processing, and latent space diffusion methods. However, these techniques are generally designed to accelerate inference for a single image instance.

U.S. patent application Ser. No. 18/403,170 (referred to as the '170 application below) proposes an early sampling step sharing mechanism for DDPM-based image restoration workflows. This mechanism allows a group of images to share the initial time steps of the reverse diffusion, thereby reducing redundant calculations across continuous image instances.

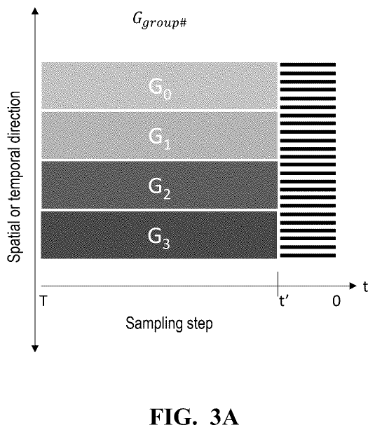

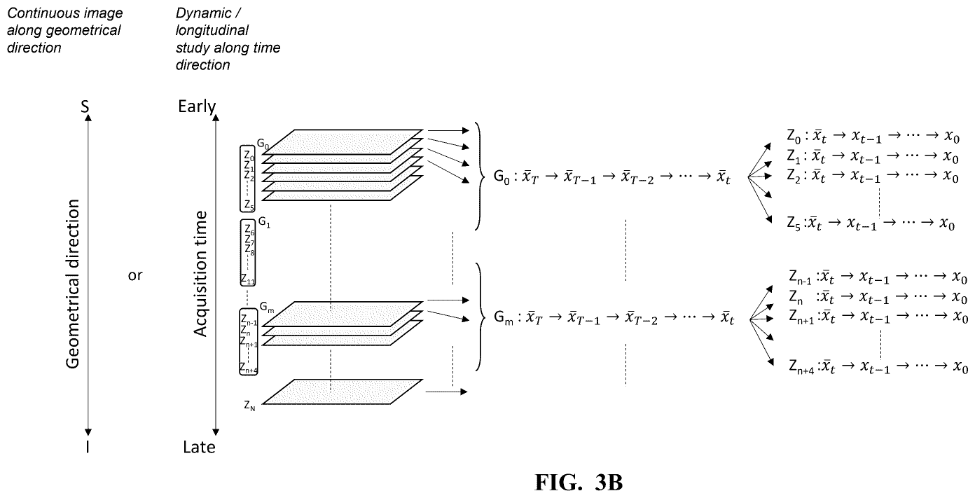

As shown in FIG. 3A, a set of images (e.g., 24 images) sequentially acquired along a spatial or temporal direction is divided into a plurality of groups, e.g., groups G₀, G₁, G₂, and G₃. For each group, the early time steps from T to t′ are shared across all images within the group. After that, the reverse diffusion process is performed individually for each image.

FIG. 3B further illustrates a schematic of the shared sampling workflow for a series of (N+1) images Z₀, Z₁, . . . , Z_{N}, which are acquired sequentially along a geometrical or temporal direction. The images are divided into groups G₀ to Gₘ. Each group undergoes a shared reverse diffusion process from the time step T to an intermediate time step t, generating a representative intermediate image x̅ₜ for the group. This shared intermediate image x̅ₜ is then used as a starting point for individual denoising processes of the images within the group, generating a final output x₀ for each image.

Accordingly, this workflow includes two stages: (1) a shared reverse diffusion phase from the time step T to t, and (2) an individualized refinement phase from the time step t to 0. By sharing the early denoising steps across images within a same group, this method can reduce the overall computational cost without sacrificing image quality.

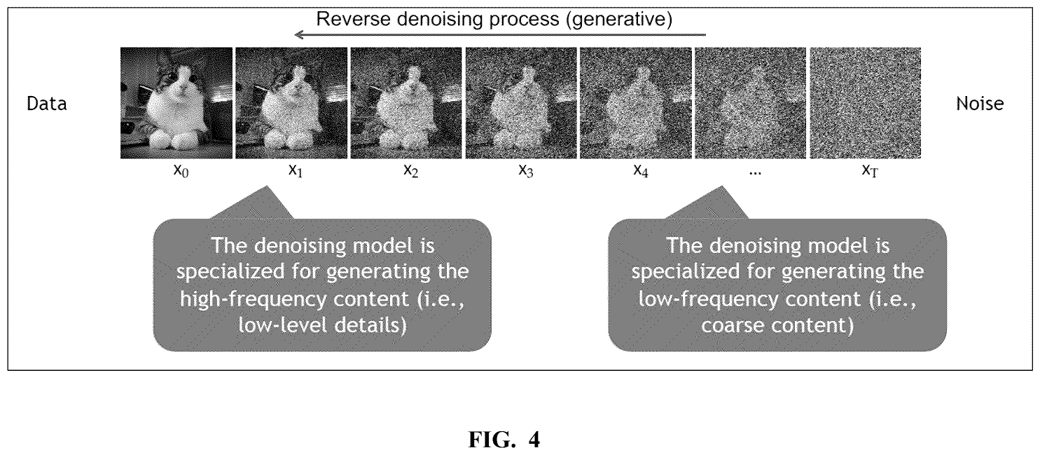

FIG. 4 shows that a diffusion model restores an image by reversing noise from x_{T}(pure noise) to a final output image x₀. At time steps with larger t values (i.e., closer to x_{T}), the denoising model is specialized for generating low-frequency content, such as coarse features. These coarse features tend to be shared across continuous images, for example, adjacent spatial slices, temporally adjacent images, etc. As the process proceeds toward time steps with smaller t values (i.e., closer to x₀), the denoising model is specialized for generating the high-frequency content, for example, low-level details.

This coarse-to-fine denoising behavior enables a tiered sampling step sharing strategy to be implemented. Specifically, the reverse denoising steps can be shared with varying group granularity in multiple stages. In earlier stages with larger t values, the images can be grouped more broadly. As the process moves toward later stages with smaller t values, the number of groups increases. Eventually, the final denoising steps are performed individually on each image to fully recover the image-specific details.

By using fewer groups at earlier stages and more groups at later stages, this tiered time step sharing can achieve a balance between processing time and image quality. It is especially effective for bulk image processing tasks such as volumetric CT reconstruction or longitudinal imaging, where structural similarities across continuous images can be exploited to accelerate inference without compromising the quality of the final outputs.

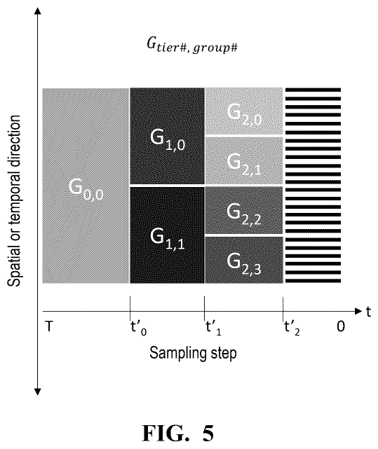

FIG. 5 illustrates a schematic of the tiered sampling step sharing strategy in accordance with one embodiment of the disclosure. As illustrated, the reverse sampling process is divided into multiple stages, such that the full image set is progressively divided into increasingly finer groups in a tiered manner.

For example, in the earliest tier (Tier 0), all images belong to a single group G_{0,0}, which shares the entire sequence of denoising steps from the time step T to t′₀. In Tier 1, the images are split into two groups (G_{1,0} and G_{1,1}), with each group sharing reverse steps from the time step t′₀ to t′₁. In Tier 2, the grouping is further refined into four groups (G_{2,0}, G_{2,1}, G_{2,2}, and G_{2,3}), and images in each group share reverse steps from the time step t′₁ to t′₂. For the final time steps (from t′₂ to 0), each image is processed individually to recover fine details.

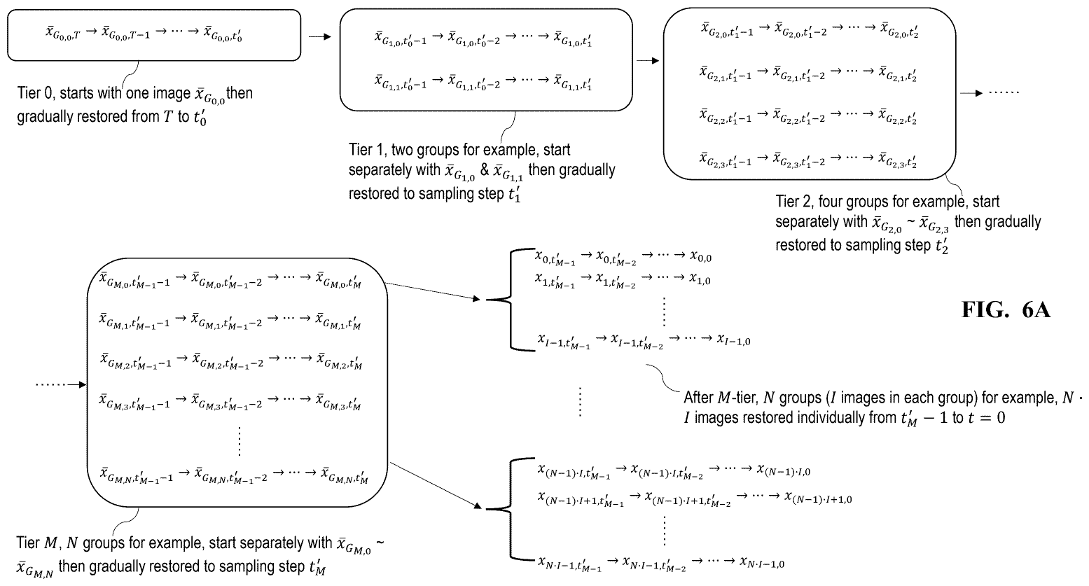

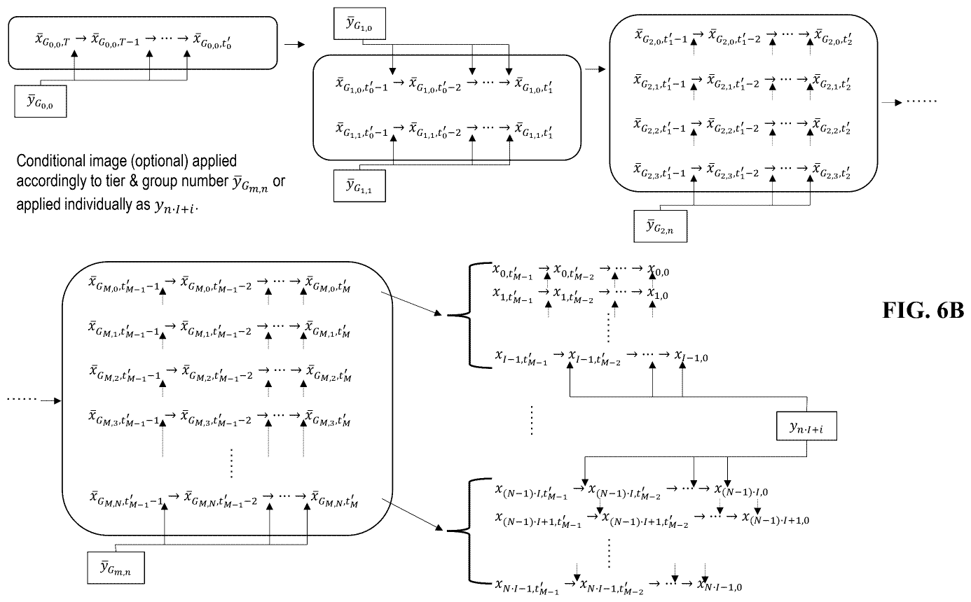

FIG. 6A shows a workflow of the tiered time step sharing strategy in accordance with one embodiment of the disclosure. Each box in the diagram represents reverse sampling operations performed within a tier.

In Tier 0, which includes only one group, a representative image x̅_{G}_{_{0,0,}}_{T} undergoes denoising steps from the initial time step T to an intermediate time step t′₀. The resulting intermediate image x̅_{G}_{_{0,0,}}ₜ_{₀}_{′} is then used as the starting point for the next tier.

In one embodiment, the representative image for the group G_{0,0} can be the average of all images within the group. Alternatively, an image that contains the most structural information or has the best image quality can be selected as the representative image of the group. There is no restriction on how the representative image is selected or generated. One skilled in the art can apply various approaches to obtain the representative image.

In Tier 1, two groups, i.e., G_{1,0} and G_{1,1}, separately perform reverse denoising from the time step t′₀−1 to t′₁, each starting from the intermediate image x̅_{G}_{_{0,0,}}ₜ_{₀}_{′} generated in Tier 0. Similarly, in Tier 2, four groups, i.e., G_{2,0}, G_{2,1}, G_{2,2}, and G_{2,3}, perform reverse denoising from the time step from the time step t′₁−1 to t′₂, using the outputs of Tier 1 as their respective starting points. The process proceeds tier by tier with increasingly finer groupings, until the final stage after Tier M, where all individual images are processed independently from the time step t′_{M}−1 to 0 without sharing.

This tiered workflow reduces computational redundancy at early stages by grouping images that share coarse structural similarity. For each group, a plurality of reverse denoising steps are shared. As the process advances through the tiers, the number of groups increases, and the group sizes become smaller. In the final stage, all individual images are restored separately without sharing, which ensures accurate reconstruction of fine structural details within the images. By combining early-stage sharing with late-stage individualized processing, this approach achieves a balanced tradeoff between computational efficiency and reconstruction quality.

As discussed previously, in scenarios such as medical image processing, conditional images can be used as guide during the training and inference processes, allowing the diffusion model to incorporate additional context or constraints.

FIG. 6B illustrates the use of conditional images to guide the restoration process in accordance with one embodiment of the disclosure. These conditional images can be applied at both the group level in each tier (e.g., y̅_{G}_{_{0,0}}, y̅_{G}_{_{1,0}}, y̅_{G}_{_{1,1}}, etc.) and at the individual image level (e.g., y_{n·1+i}). For example, a conditional image can be a low-resolution, high-noise version of the target CT image being restored. By introducing contextual constraints, the diffusion model can be guided toward generating a specific desired output, instead of generating an arbitrary image.

Each arrow from a conditional image to a denoising step in FIG. 6B indicates the influence of that image on the corresponding denoising step. For example, y̅_{G}_{_{0,0}} can be used for the group G_{0,0} across all reverse denoising steps in Tier 0, and can be generated by averaging the conditional images for the group G_{0,0}. In Tier 1, the groups G_{1,0} and G_{1,1} are guided by their respective conditional images y̅_{G}_{_{1,0}} and y̅_{G}_{_{1,1}}. The same approach applies to subsequent tiers. After the final sharing tier, individual restoration is performed for each image, guided by its own specific conditional image.

According to one embodiment of this disclosure, the number of groups increases as the time steps approach 0. In addition, the number of sampling steps shared in each tier can vary across tiers. For example, in one implementation, Tiers 0-3 cover 100, 50, 40, and 5 steps, respectively, while in another implementation, Tiers 0-3 cover 170, 10, 10, and 5 steps. In general, later tiers tend to correspond to shorter sampling lengths and more individualized processing, with the final sampling steps performed independently without sharing.

For example, a tiered sampling step sharing restoration workflow can process 1200 slices using four sharing tiers. Tier 0 shares among the entire volume (slices 1-1200) and covers the sampling steps t=200 to t=100. Tier 1 divides the slices into two groups (slices 1-600 and slices 601-1200) and covers the sampling steps t=99 to t=50. Tier 2 further divides the slices into four groups (slices 1-300, 301-600, 601-900, and 901-1200), sharing the sampling steps t=49 to t=10. Tier 3 refines the sharing into eight groups (e.g., slices 1-150, 151-300, . . . , 1051-1200), covering the time steps t=9 to t=5. Finally, from t=4 to t=1, all slices are processed individually without sharing.

Although the example above uses equal-sized groups for simplicity, the groups within a tier do not need to include the same number of slices. In practice, group boundaries can be flexibly defined based on structural similarity, anatomical landmarks, or acquisition timing, for example.

Accordingly, three sharing parameters can be tuned to balance the processing time and image quality at different levels of the workflow:
(1) Tier number. This parameter determines the number of levels (tiers) in the hierarchical processing workflow.
(2) Group number in each tier. This parameter determines the number of groups that are formed within the tier for shared processing.
(3) Sampling length in each tier. This parameter determines the range of sampling steps (e.g., t values) covered by the tier.

These sharing parameters can be empirically selected based on the characteristics of a specific image set. By configuring the three parameters appropriately, the workflow can be adapted for clinical applications, achieving an optimal balance between computational acceleration and the quality of the final restored images. Alternatively, an automated approach can be developed for clinical use, wherein the sharing parameters are selected based on their estimated impact on the processing speed and image quality.

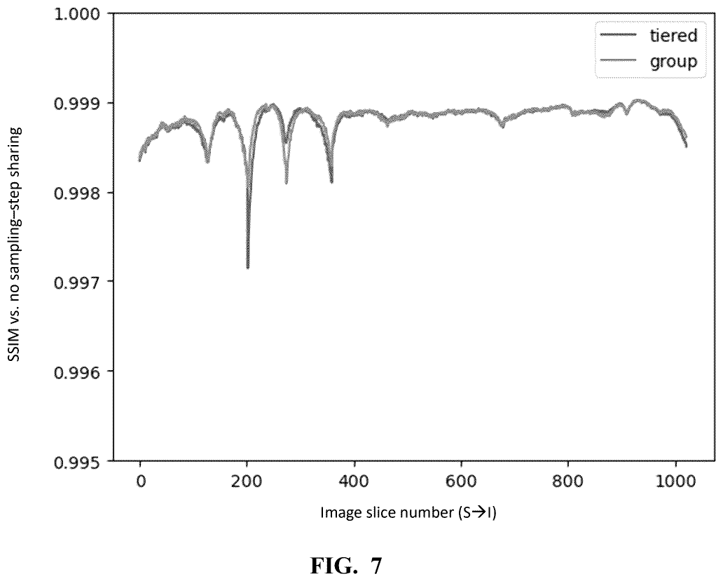

FIG. 7 illustrates the structural similarity index (SSIM) across a 1022-slice image stack processed using two different acceleration approaches: (1) the sampling step sharing method described in the '170 application, and (2) the tiered sampling step sharing method proposed in this disclosure. A regular DDPM without sharing is used as the baseline for comparison.

In this example, the total number of sampling steps is 200. Therefore, the conventional slice-by-slice processing without any sharing requires:

$$1022 \times 200 = 204.4 k inference steps .$$

The proposed tiered approach uses 4 tiers, with the group numbers in each tier set as 1, 2, 4, and 8, and corresponding sampling lengths of 170, 10, 10, and 5 steps. After the last sharing tier, an additional 5 individual steps are applied to each slice. Accordingly, the total number of inference steps for the tiered approach is:

$$1 \times 170 + 2 \times 10 + 4 \times 10 + 8 \times 5 + 1022 \times 5 = 5.38 k inference steps .$$

By comparison, the sharing method in the '170 application uses 8 groups for a shared duration of t′=5, followed by individual processing. The total number of inference steps required in this method is:

$$8 \times 195 + 1022 \times 5 = 6.67 k inference steps .$$

Thus, the proposed tiered sharing method reduces inference steps by nearly 20% compared to the '170 application, while preserving a high restoration quality, with SSIM>0.997 across all slices. Although the processing time remains approximately 5 or 6 times longer than a conventional 2D inference model, the tiered sharing approach achieves a favorable balance between efficiency and image quality in volumetric restoration tasks. This essentially increases the practicality of applying diffusion-based approaches in daily imaging routine.

Note that all of the above numerical examples are illustrative and not intended to be limiting. A person of ordinary skill in the art can freely select the number of sampling steps assigned to each tier based on the needs of a particular implementation. For example, while the provided examples show configurations in which a preceding tier includes an equal or greater number of sampling steps than a following tier, it is also possible for a preceding tier to include fewer sampling steps than a following tier.

This tiered sharing approach is particularly effective for processing large volumes of imaging data, such as continuous image acquisitions along a geometrical direction or dynamic/longitudinal studies along a temporal direction. The continuity among the images can arise from various sources, including, but not limited to, spatial adjacency in anatomical scans, temporal progression in dynamic imaging, or a combination thereof. Thus, the proposed method can be broadly applied to any form of continuous data, whether spatial, temporal, or hybrid.

Furthermore, this method can also be extended to non-continuous datasets, provided that a proper image registration technique is applied to align the images and establish continuity.

Even though the embodiments and examples are described in the context of 2D images such as individual slices of a CT scan, one skilled in the art will appreciate that the tiered sharing concept can also be applied to higher-dimensional image data, as long as the individual data units have meaningful correlation with each other.

The proposed tiered sharing method is compatible with acceleration approaches that are applicable to single image process, and thus can be integrated with those acceleration techniques. Furthermore, the proposed method is not limited to medical imaging or image restoration applications. Instead, it can be applied to various imaging types and image processing tasks.

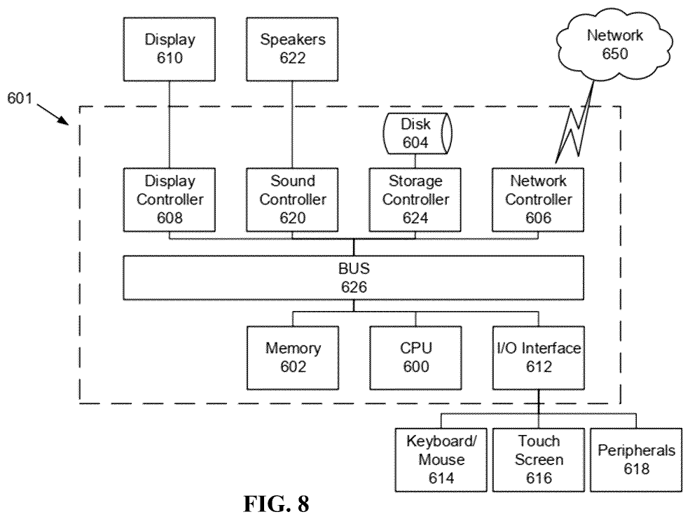

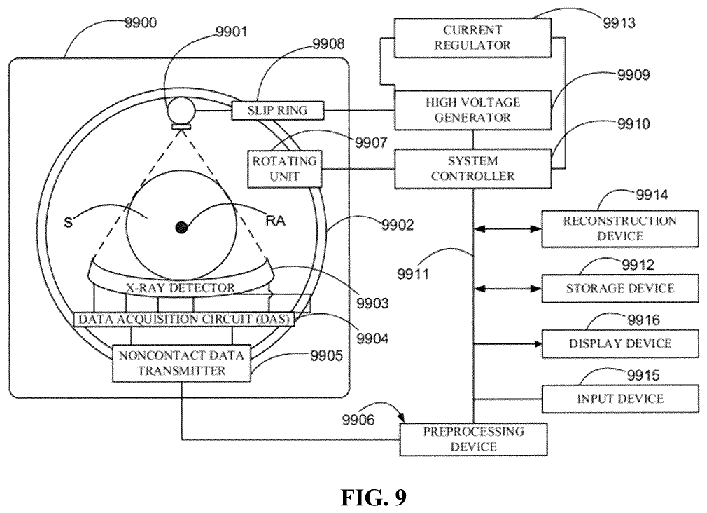

Next, a hardware description of a device 601 according to exemplary embodiments is described with reference to FIG. 8. In FIG. 8, the device 601 includes processing circuitry. The device 601 can be used to execute any of the methods described herein related to obtaining the DDPM, training the DDPM, receiving acquired images, and/or denoising an image using the DDPM. In one embodiment, the device 601 can be a server, a computer, etc. In one embodiment, the device 601 can be in communication with or embedded in an image acquisition device, such as the CT device illustrated in FIG. 9. In one embodiment, the methods described herein can be distributed across one or more devices, the one or more devices including at least some of the elements of device 601. The processing circuitry includes one or more of the elements discussed next with reference to FIG. 8. The process data and instructions may be stored in memory 602. These processes and instructions may also be stored on a storage medium disk 604 such as a hard drive (HDD) or portable storage medium or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, hard disk or any other information processing device with which the device 601 communicates, such as a server or computer.

Further, the claimed advancements may be provided as a utility application, background daemon, or component of an operating system, or combination thereof, executing in conjunction with CPU 600 and an operating system such as Microsoft Windows, UNIX, Solaris, LINUX, Apple MAC-OS and other systems known to those skilled in the art.

The hardware elements in order to achieve the device 601 may be realized by various circuitry elements, known to those skilled in the art. For example, CPU 600 may be a Xenon or Core processor from Intel of America or an Opteron processor from AMD of America, or may be other processor types that would be recognized by one of ordinary skill in the art. Alternatively, the CPU 600 may be implemented on an FPGA, ASIC, PLD or using discrete logic circuits, as one of ordinary skill in the art would recognize. Further, CPU 600 may be implemented as multiple processors cooperatively working in parallel to perform the instructions of the processes described above.

The device 601 in FIG. 8 also includes a network controller 606, such as an Intel Ethernet PRO network interface card from Intel Corporation of America, for interfacing with network 650, and to communicate with the other devices. As can be appreciated, the network 650 can be a public network, such as the Internet, or a private network such as an LAN or WAN network, or any combination thereof and can also include PSTN or ISDN sub-networks. The network 650 can also be wired, such as an Ethernet network, or can be wireless such as a cellular network including EDGE, 3G, 4G and 5G wireless cellular systems. The wireless network can also be WiFi, Bluetooth, or any other wireless form of communication that is known.

The device 601 further includes a display controller 608, such as a NVIDIA GeForce GTX or Quadro graphics adaptor from NVIDIA Corporation of America for interfacing with display 610, such as an LCD monitor. A general purpose I/O interface 612 interfaces with a keyboard and/or mouse 614 as well as a touch screen panel 616 on or separate from display 610. General purpose I/O interface also connects to a variety of peripherals 618 including printers and scanners.

A sound controller 620 is also provided in the device 601 to interface with speakers/microphone 622 thereby providing sounds and/or music.

The general purpose storage controller 624 connects the storage medium disk 604 with communication bus 626, which may be an ISA, EISA, VESA, PCI, or similar, for interconnecting all of the components of the device 601. A description of the general features and functionality of the display 610, keyboard and/or mouse 614, as well as the display controller 608, storage controller 624, network controller 606, sound controller 620, and general purpose I/O interface 612 is omitted herein for brevity as these features are known.

In one embodiment, the images processed using the bulk diffusion methods described herein can be CT images acquired by a CT apparatus or scanner. FIG. 9 illustrates an implementation of a radiography gantry included in a CT apparatus or scanner. As shown in FIG. 9, a radiography gantry 9900 is illustrated from a side view and further includes an X-ray tube 9901, an annular frame 9902, and a multi-row or two-dimensional-array-type X-ray detector 9903. The X-ray tube 9901 and X-ray detector 9903 are diametrically mounted across an object, such as, for example, a patient, on the annular frame 9902, which is rotatably supported around a rotation axis RA. A rotating unit 9907 rotates the annular frame 9902 at a high speed, such as, for example, 0.4 sec/rotation, while the object is being moved along the axis RA into or out of the illustrated page.

An embodiment of an X-ray computed tomography (CT) apparatus according to the present application will be described below with reference to the views of the accompanying drawing. Note that X-ray CT apparatuses include various types of apparatuses, e.g., a rotate/rotate-type apparatus in which an X-ray tube and X-ray detector rotate together around an object to be examined, and a stationary/rotate-type apparatus in which many detection elements are arrayed in the form of a ring or plane, and only an X-ray tube rotates around an object to be examined. The present application can be applied to either type. In this case, the rotate/rotate type, which is currently the mainstream, will be exemplified.

The multi-slice X-ray CT apparatus further includes a high voltage generator 9909 that generates a tube voltage applied to the X-ray tube 9901 through a slip ring 9908 such that the X-ray tube 9901 generates X-rays. An X-ray detector 9903 is located at an opposite side from the X-ray tube 9901 across the object for detecting the emitted X-rays that have transmitted through the object. The X-ray detector 9903 is for example a photon-counting detector. The X-ray detector, or the photon-counting detector 9903 further includes individual detector elements or units, such as, for example, processing circuitry.

The CT apparatus further includes other devices for processing the detected signals from X-ray detector 9903. A data acquisition circuit or a Data Acquisition System (DAS) 9904 converts a signal output from the X-ray detector 9903 for each channel into a voltage signal, amplifies the signal, and further converts the signal into a digital signal. The X-ray detector 9903 and the DAS 9904 are configured to manage a predetermined total number of projections per rotation (TPPR).

The above-described data is sent to a preprocessing device 9906, which is housed in a console outside the radiography gantry 9900 through a non-contact data transmitter 9905. The preprocessing device 9906 performs certain corrections. A memory 9912 stores the resultant data, which is also called projection data at a stage immediately before reconstruction processing. The memory 9912 is connected to a system controller 9910 through a data/control bus 9911, together with a reconstruction device 9914, input device 9915, and display 9916. The system controller 9910 controls a current regulator 9913 that limits the current to a level sufficient for driving the CT system.

The detectors are rotated and/or fixed with respect to the object being scanned, such as the patient, among various generations of the CT scanner systems. In one implementation, the above-described CT system can be an example of a combined third-generation geometry and fourth-generation geometry system. In the third-generation system, the X-ray tube 9901 and the X-ray detector 9903 are diametrically mounted on the annular frame 9902 and are rotated around the object as the annular frame 9902 is rotated about the rotation axis RA. In the fourth-generation geometry system, the detectors are fixedly placed around the patient and an X-ray tube 9901 rotates around the patient. In an alternative embodiment, the radiography gantry 9900 has multiple detectors arranged on the annular frame 9902, which is supported by a C-arm and a stand.

Post-reconstruction processing performed by the reconstruction device 9914 can include filtering and smoothing the image, volume rendering processing, and image difference processing as needed. The image reconstruction process can implement various CT image reconstruction methods. The reconstruction device 9914 can use the memory to store, e.g., projection data, reconstructed images, calibration data and parameters, and computer programs.

While this specification contains many specific implementation details, these should not be construed as limitations on the scope of what may be claimed, but rather as descriptions of features that may be specific to particular embodiments.

Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the embodiments described above should not be understood as requiring such separation in all embodiments, and it should be understood that the described program components and systems can generally be integrated together in a single software product or packaged into multiple software products.

Particular embodiments of the subject matter have been described. Other embodiments are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

Embodiments of the present application may also be as set forth in the following parentheticals.

(1) A method for performing diffusion-based image processing on a plurality of input images, the method comprising: obtaining a diffusion-based probabilistic model (DDPM) that was trained to restore a target image from noise over T sampling steps, wherein T is an integer greater than or equal to 3; dividing the T sampling steps into M tiers, wherein M is an integer greater than or equal to 3; and processing the plurality of input images in a tier-by-tier manner using the obtained DDPM, to generate a plurality of processed images, wherein in each tier of a first M−1 tiers, the processing further comprises: grouping the plurality of input images into one or more groups, and over a sampling step within the tier, for each group of the one or more groups, performing shared diffusion-based image processing on a representative image of the group, so as to generate a representative intermediate image, which is used as a starting point for the diffusion-based image processing in a subsequent tier, and wherein in a last tier of the M tiers, the processing further comprises: over a sampling step within the last tier, performing diffusion-based image processing independently with respect to each image of the plurality of input images, without sharing.

(2) The method of (1), further comprising, within the first M−1 tiers, grouping the plurality of input images into fewer groups in a preceding tier than in a following tier.

(3) The method of (1), wherein within the M tiers, a preceding tier spans either a greater number of sampling steps or a same number of sampling steps as a following tier.

(4) The method of (1), further comprising, in a first tier of the M tiers, grouping the plurality of input images into a single group, and the representative image of the single group is: generated as an average of the plurality of input images, or selected, from the plurality of input images, as an image that contains more structural features or exhibits a better image quality than other images among the plurality of input images.

(5) The method of (1), wherein the plurality of input images comprise a series of continuous images.

(6) The method of (5), wherein the series of continuous images comprise a series of images acquired sequentially over a spatial direction.

(7) The method of (5), wherein the series of continuous images comprise a series of images acquired sequentially over a temporal direction.

(8) The method of (5), wherein the series of continuous images comprise a series of images aligned through an image registration procedure.

(9) The method of (1), further comprising inputting a conditional image into the obtained DDPM to guide the diffusion-based image processing through a contextual constraint.

(10) The method of (1), further comprising acquiring the plurality of input images from a scan performed using a medical imaging system on an imaging object.

(11) An apparatus for performing diffusion-based image processing on a plurality of input images, the apparatus comprising: processing circuitry configured to obtain a diffusion-based probabilistic model (DDPM) that was trained to restore a target image from noise over T sampling steps, wherein T is an integer greater than or equal to 3, divide the T sampling steps into M tiers, wherein M is an integer greater than or equal to 3, and process the plurality of input images in a tier-by-tier manner using the obtained DDPM, to generate a plurality of processed images, wherein for each tier of a first M−1 tiers, the processing circuitry is further configured to: group the plurality of input images into one or more groups, and over a sampling step within the tier, for each group of the one or more groups perform shared diffusion-based image processing on a representative image of the group, so as to generate a representative intermediate image, which is used as a starting point for the diffusion-based image processing in a subsequent tier, and wherein for a last tier of the M tiers, the processing circuitry is further configured to: over a sampling step within the last tier, perform diffusion-based image processing independently with respect to each image of the plurality of input images, without sharing.

(12) The apparatus of (11), wherein the processing circuitry is further configured to, within the first M−1 tiers, group the plurality of input images into fewer groups in a preceding tier than in a following tier.

(13) The apparatus of (11), wherein within the M tiers, a preceding tier spans either a greater number of sampling steps or a same number of sampling steps as a following tier.

(14) The apparatus of (11), wherein in a first tier of the M tiers, the processing circuitry is further configured to group the plurality of input images into a single group, and the representative image of the single group is: generated as an average of the plurality of input images, or selected, from the plurality of input images, as an image that contains more structural features or exhibits a better image quality than other images among the plurality of input images.

(15) The apparatus of (11), wherein the plurality of input images comprise a series of continuous images.

(16) The apparatus of (15), wherein the series of continuous images comprise a series of images acquired sequentially over a spatial direction.

(17) The apparatus of (15), wherein the series of continuous images comprise a series of images acquired sequentially over a temporal direction.

(18) The apparatus of (15), wherein the series of continuous images comprise a series of images aligned through an image registration procedure.

(19) The apparatus of (11), wherein the processing circuitry is further configured to input a conditional image into the obtained DDPM to guide the diffusion-based image processing through a contextual constraint.

(20) A non-transitory computer-readable storage medium for storing computer readable instructions that, when executed by a computer, cause the computer to perform a method for performing diffusion-based image processing on a plurality of input images, the method comprising: obtaining a diffusion-based probabilistic model (DDPM) that was trained to restore a target image from noise over T sampling steps, wherein T is an integer greater than or equal to 3; dividing the T sampling steps into M tiers, wherein M is an integer greater than or equal to 3; and processing the plurality of input images in a tier-by-tier manner using the obtained DDPM, to generate a plurality of processed images, wherein in each tier of a first M−1 tiers, the processing further comprises: grouping the plurality of input images into one or more groups, and over a sampling step within the tier, for each group of the one or more groups, performing shared diffusion-based image processing on a representative image of the group, so as to generate a representative intermediate image, which is used as a starting point for the diffusion-based image processing in a subsequent tier, and wherein in a last tier of the M tiers, the processing further comprises: over a sampling step within the last tier, performing diffusion-based image processing independently with respect to each image of the plurality of input images, without sharing.

Obviously, numerous modifications and variations are possible in light of the above teachings. It is therefore to be understood that within the scope of the appended claims, embodiment of the present application may be practiced otherwise than as specifically described herein.

Paragraphs [00121]-[00177] below are derived from U.S. application Ser. No. 18/796,076 and included as part of this continuation-in-part application.

In one embodiment, the present disclosure is directed to systems and methods for image restoration using deep learning-based models. Image restoration techniques can include, but are not limited to, denoising, deblurring, resolution enhancement (e.g., super-resolution imaging), and image/signal reconstruction (e.g., compressed sensing). Each of these techniques can be used independently or in combination to improve the visibility of features in an image. Image restoration has important applications for medical imaging modalities such as computed topography (CT) scanning, magnetic resonance imaging (MRI), etc., which are often subject to noise due to physical interactions within the imaging systems. It can be appreciated that the systems and methods described herein are not limited to medical imaging applications and can be used for various imaging types and techniques. In particular, the methods of the present disclosure can be useful for processing any volumes of image data (e.g., a series of images or image slices) that are acquired over a spatial or temporal span.

Generative deep learning-based models can be used to reduce noise and similar artifacts in an acquired image in order to generate a restored image that is of higher quality than the acquired image. In one embodiment, a generative model can be used to denoise an image by converting a first data distribution (noisy image data) to a second data distribution (restored image data). In one embodiment, the generative model can be a denoising diffusion probabilistic model (DDPM). It can be appreciated that DDPMs are described herein as an illustrative example of a class of generative models, and that other types of probabilistic models and especially diffusion-based probabilistic models for image restoration are also compatible with the methods of the present disclosure.

A DDPM can be used to denoise an image in a series of diffusion steps. The DDPM can be trained to denoise an image in an iterative process, wherein the DDPM generates an increasingly denoised image at each diffusion step. The DDPM can be trained to denoise an image by converting a first probability distribution corresponding to an input image (e.g., a noisy image) to a second probability distribution corresponding to an output image (e.g., a denoised image). In one example, the first probability distribution can be a normal distribution corresponding to normal (Gaussian) noise that is present in an acquired image. The DDPM can be trained to remove the noise by converting the normal probability distribution to a predicted distribution corresponding to a denoised, restored image.

In one embodiment, a DDPM can be trained using a set or sequence of training images. The set of training images can include a target image, which is a clean or denoised image, and noisy images that are generated from the target image. In one embodiment, the noisy training images can be generated by applying modeled noise (e.g., Gaussian noise) to the target image in one or more steps. The set of training images can include images with increasing amounts of noise. The set of training images can further include a pure noise image generated from the target image. In one embodiment, the modeled noise can be similar to or based on an expected type of noise in an acquired image that the DDPM will be used to restore. In one embodiment, the target image can be similar to or based on a type of image that the DDPM will be used to recover. The training images can each be input to the DDPM. The DDPM can be trained to denoise an input training image to output a restored image at each step in a series of diffusion steps. The series of diffusion steps can correspond to the one or more steps used to apply noise to the target image. In this manner, the DDPM can be trained to “reverse” a stepwise process for applying noise to an image in order to remove said noise from the image.

At each diffusion step, the DDPM can be trained to minimize a loss function, the loss function corresponding to a difference in noise between a predicted output image and a training image for the given diffusion step. The DDPM can therefore be trained to accurately predict and model a difference in noise between each input image and an output image at each diffusion step. In one embodiment, the training of the DDPM can include setting one or more weights of the model. The one or more weights of the model can vary for each diffusion step within the series of diffusion steps or for at least one of the diffusion steps within the series. In one embodiment, a conditional image can be input to the DDPM during the training process to guide the generation of output images. In one embodiment, the conditional image can be the target image. The target image used for training the DDPM can be at least one target image and can include more than one target image. For example, the at least one target image can include a low-resolution medical image (e.g., CT image) and an edge-detected medical image (e.g., CT image) or otherwise processed medical image. Similarly, the conditional image used for training the DDPM can be at least one conditional image and can include more than one conditional image. In one example, the at least one conditional image can include a low-resolution medical image (e.g., CT image) and an edge-detected medical image (e.g., CT image), or otherwise processed medical image. In one example, the at least one conditional image or the at least one target image can include three consecutive conditional images for a multi-dimensional (e.g., 2.5 dimensional) process.

In one embodiment, the input to a trained DDPM can be a noisy image, a conditional image, and a diffusion step (also referred to as a time step or sampling step). The DDPM can predict the second probability distribution corresponding to a restored image given the conditional image as a known condition. In one embodiment, the DDPM can denoise a pure noise image in a series of diffusion steps in order to generate a final restored image. The pure noise image can be the first image input to the DDPM. The DDPM can output a denoised image (also referred to herein as a restored image) for each diffusion step. The denoised image output from each diffusion step in the series can be input into a following diffusion step in order to iteratively denoise the pure noise image. The DDPM can include one or more learned weights used to output the restored image, wherein the value of the one or more learned weights can be dependent on the diffusion step. Additional details regarding the training and use of a DDPM for can be found in Ho, J. et. al, (2020). “Denoising diffusion probabilistic models.” Advances in neural information processing systems, 33, 6840-6851 and in Xia, W. et. al, (2022). “Low-Dose CT Using Denoising Diffusion Probabilistic Model for 20× times Speedup.” arXiv preprint arXiv:2209.15136, each of which is incorporated herein by reference in its entirety for all purposes.

In one embodiment, the DDPM can be used to denoise a series of images. The series of images can be acquired in sequence over time or over a spatial dimension. For example, a series of images can be acquired over time via a renal scan in order to evaluate kidney function. In the denoising process (also referred to as an inference process or sampling process), the DDPM can denoise and identify larger or more generalized features in initial denoising (diffusion) steps. These larger features are typically consistent throughout a series of images. For example, the general shape and location of the kidney and structures therein can first be identified in a scan image and are not likely to change within a single renal scan. The DDPM can then denoise and identify smaller features or details in later diffusion steps. In the example of a renal scan, the DDPM can identify finer details of the shape and size of renal structures, as well as the location of any contrast dye within the kidney. These details can change throughout the series of images as the renal system processes fluid in the body. Changes throughout the series of images are likely to be gradual and continuous over time. Therefore, adjacent images in a series of images can be similar to each other.

In another example, a series of images can be acquired through a scan of one or more sections of the body along one or more directions. In a similar manner, the DDPM can first denoise and identify larger features such as the general shape of the section of the body and organs therein. The DDPM can then denoise and identify smaller features and/or finer details of the organs. Adjacent images within the series depict portions of the body that are also in close proximity with each other. Therefore, the adjacent images in the series are also likely to be similar to each other and share large features as the scan progresses along the body.

In another example, a series of images can be acquired in sequence over time and while a contrast agent is processed by the patient's body. Multiphasic imaging, which can be used in CT and MRI, is a technique that includes acquiring scans at different time points after an injection of the intravenous contrast. Multiphasic imaging can be performed to optimize the visualization of different structures or pathologies that have different contrast enhancement patterns. Multiphasic imaging can help detect and characterize vascular lesions, tumors, ischemia, inflammation, or trauma in various organs. By comparing the images obtained at different phases, such as a non-contrast phase, an arterial phase, a (portal) venous phase, and/or a delayed phase, a radiologist or similar operator can assess a blood flow, perfusion, and excretion of contrast in tissues of interest. Notably, for a multiphasic imaging dataset, which usually includes 3 to 4 times the total volume of images compared to single phase imaging, the total processing time for diffusion-based restoration will be incredibly lengthy. Thus, a cross-acquisition acceleration mechanism is desired.

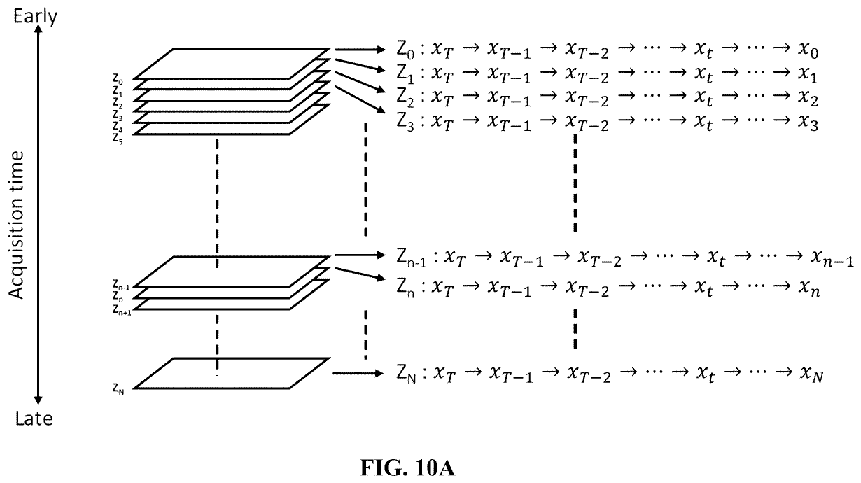

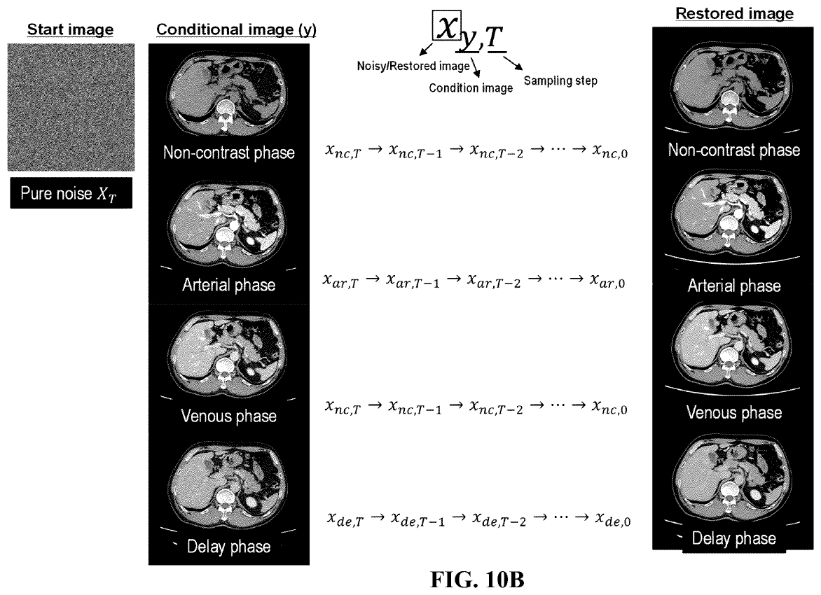

FIG. 10A is a schematic of a process for denoising a series of N images (Z₀, Z₁, Z₂, Z₃, Z₄, Z₅, . . . Z_{N}) using a trained DDPM. The series of N images can be collected over a period of time or along a spatial direction. For each image in the series of images, a pure noise image x_{T} can be input to the DDPM. The pure noise image x_{T} can be generated using a probability distribution model, such as a Gaussian distribution. A conditional image can also be input to the DDPM for the denoising process. In one embodiment, the conditional image can be the image (one of the series Z₀, Z₁, Z₂, Z₃, Z₄, Z₅, . . . Z_{N}) that is being denoised. The conditional image can include more than one conditional images, such as an edge-detected image or otherwise processed image.

The DDPM can be used to denoise each image (Z₀, Z₁, Z₂, Z₃, Z₄, Z₅, . . . Z_{N}) in a series of T diffusion steps. The DDPM can denoise the pure noise image x_{T} in a series of T diffusion steps to generate a corresponding sequence of restored images x_{T-1}, x_{T-2}, etc. for each image in the series. At each diffusion step, the restored image from the previous diffusion step can be input to the DDPM along with the conditional image and the timestep (T−1, T−2, etc.). For example, the DDPM can denoise the pure noise image x_{T} based on the conditional image Z₀ to generate the restored image x_{T-1} at time step T−1. The DDPM can then denoise the image x_{T-1} based on the conditional image Z₀ to generate a further restored image x_{T-2} at time step T−2. At time step T, the DDPM can output an image x₀ that is a denoised version of the conditional image Z₀. After T time steps for each image (Z₀, Z₁, Z₂, Z₃, Z₄, Z₅, . . . Z_{N}), the DDPM can output a corresponding denoised image (x₀, x₁, x₂, x₃, x₄, x₅, . . . x_{N}). In this manner, the DDPM performs N*T diffusion steps to denoise every image in the series of images.

FIG. 10B is a schematic of a process for denoising a series of multiphasic images using a trained DDPM. The series of multiphasic images can be collected over a period of time, such as before, during, and after injection of a contrast agent. For each image in the series of multiphasic images, a pure noise image x_{T} can be input to the DDPM. The pure noise image x_{T} can be generated using a probability distribution model, such as a Gaussian distribution. A conditional image (y) can also be input to the DDPM for the denoising process. In one embodiment, the conditional image can be the image that is being denoised. The conditional image can include more than one conditional images, such as an edge-detected image or otherwise processed image. The series of multiphasic images can be divided into one or more sets of phase images. As shown, the series of multiphasic images can be divided into four sets of phase images, wherein a first set of phase images corresponds to a non-contrast phase of the imaging, a second set of phase images corresponds to an arterial phase of the imaging, a third set of phase images corresponds to a venous phase of the imaging, and a fourth set of phase images corresponds to a delay phase of the imaging.

In one embodiment, the present disclosure is directed towards bulk diffusion methods of image denoising that take advantage of similarities between adjacent images in a series of images to achieve faster denoising of the series of multiphasic images using a diffusion-based probability model. The methods described herein can reduce the number of diffusion steps needed to denoise a series of multiphasic images while retaining inference accuracy. Reducing the number of diffusion steps can result in faster denoising as well as reduced computational power usage.

In one embodiment, the method can include dividing the images in a series of multiphasic images and performing initial batch denoising on the sets of images using a trained DDPM. A set of the multiphasic images can be a subset of adjacent images within the series of multiphasic images that are collected over a period of time. The series of multiphasic images can be divided into one or more sets, wherein each set can include one or more images. Each of the one or more sets of multiphasic images can have the same or a different number of images. For example, a first set of images can include the first n images in a series, a second set of images can include the subsequent n+1 to n+m images in a series, etc. For example, the number of images in a group can be set such that one or more features or a type of feature (e.g., features of a certain size, features of a certain pixel brightness based on contrast agent level, etc.) are constant in each image of the group.

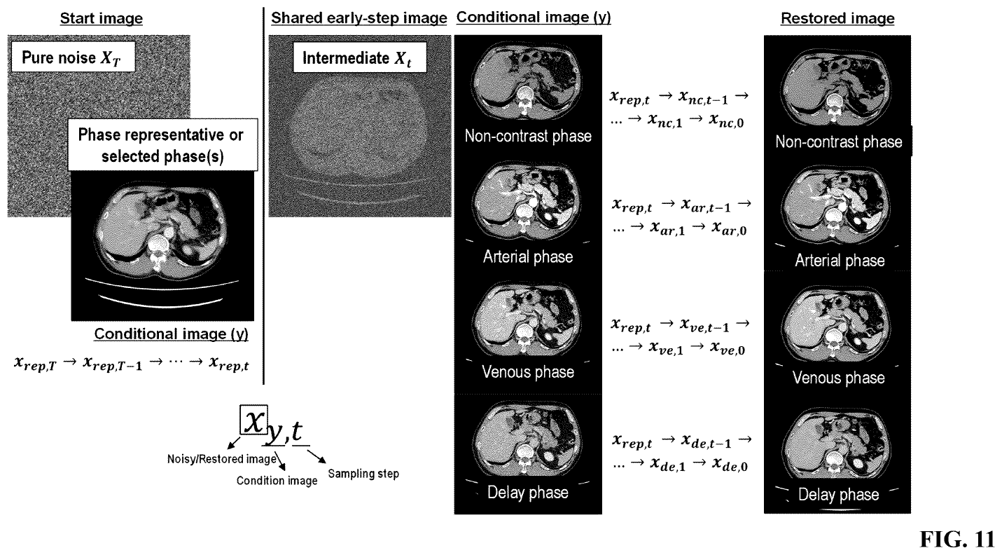

FIG. 11 is a schematic of the multiphasic imaging diffusion-based denoising method, according to one embodiment of the present disclosure. In one embodiment, a shared phase representative image can be determined for the conditional image. The shared phase representative image can be determined from the series of multiphasic images. In one example, the shared phase representative image can be generated by computing an average value for each pixel across all of the images in each set of the one or more sets of phase images. In one embodiment, the shared phase representative image can be an image of a set of the one or more sets of phase images (e.g., a first image, an nth image, an n/2th image). In one embodiment, the shared phase representative image can be a preprocessed image, such as an image that has been processed in the frequency domain and weighted. The shared phase representative image can be generated via any combination of image computation and processing and is not limited to the examples provided herein. The shared phase representative image can be input as a conditional image to the DDPM at each diffusion step in a series of initial diffusion steps. The number of initial diffusion steps can be represented by the quantity T1. The DDPM can denoise a pure noise image over T1 initial diffusion steps using the shared phase representative image as the conditional image. As will be described below, the DDPM can be trained to denoise an image in a series of T total diffusion steps, where T=T1+T2.

The features identified by the DDPM in the initial T1 diffusion steps are likely to be consistent throughout each image in the series of multiphasic images. Therefore, denoising that is conditioned on the shared phase representative image rather than on each image in the series of multiphasic images is sufficient for the initial diffusion steps for any of the images in the series of multiphasic images. The number of initial diffusion steps for which the shared phase representative image is used as a conditional image can be modulated based on the total number of diffusion steps (T), the type of scan, expected features in the series of images, etc. For example, the number of initial diffusion steps can be set such that the DDPM can identify features that are present in each image in the series of multiphasic images within the initial diffusion steps.

In one embodiment, the DDPM can output an intermediate restored image (xₜ) after the final (T1) step of the series of initial diffusion steps. The intermediate restored image can be generated by the DDPM from a pure noise image using the shared phase representative image as a conditional image. In one embodiment, the intermediate restored image can include one or more features that are shared across each multiphasic image in the series of multiphasic images. After the T1 initial diffusion steps, the appearance of each image in the series of multiphasic images may diverge. For example, the appearance of contrast agent at various intensities or locations, finer details, or smaller features can differ for each image in the series of multiphasic images. These features may not be distinguishable by the DDPM until the completion of the T1 initial diffusion steps. The T1 initial diffusion steps can result in the intermediate restored image wherein the larger and less-detailed features that the images in the series of multiphasic images have in common are denoised and visible. Therefore, the T1 initial diffusion steps can be shared among each image in the series of multiphasic images and does not need to be repeated by the DDPM for each image.

In one embodiment, the intermediate restored image generated from the T1 initial diffusion steps can be used as an input image for further diffusion steps conditioned on each image in the series of multiphasic images. The DDPM can denoise the intermediate restored image using the images in each set of the one or more sets of phase images as a conditional image to generate a restored image for each image in each set of the one or more sets of phase images. The denoising of the intermediate restored image conditioned on each image can be performed over T2 diffusion steps. The DDPM can then output final restored images corresponding to the images in each set of the one more sets of phase images. In this manner, the DDPM can reduce the number of diffusion steps needed to denoise each image in each set of the one more sets of phase images by performing a single series of T1 initial diffusion steps using the shared phase representative image as a conditional image to generate the intermediate restored image. The DDPM can then denoise the intermediate restored image in T2 diffusion steps for each image of the one or more sets of phase images to generate the output images. This method eliminates the need to repeat the T1 initial diffusion steps for each of the images in the one or more sets of phase images. The remaining T2 diffusion steps can be used to identify and denoise features that are unique to each image in the one or more sets of phase images or that are distinct in an image.

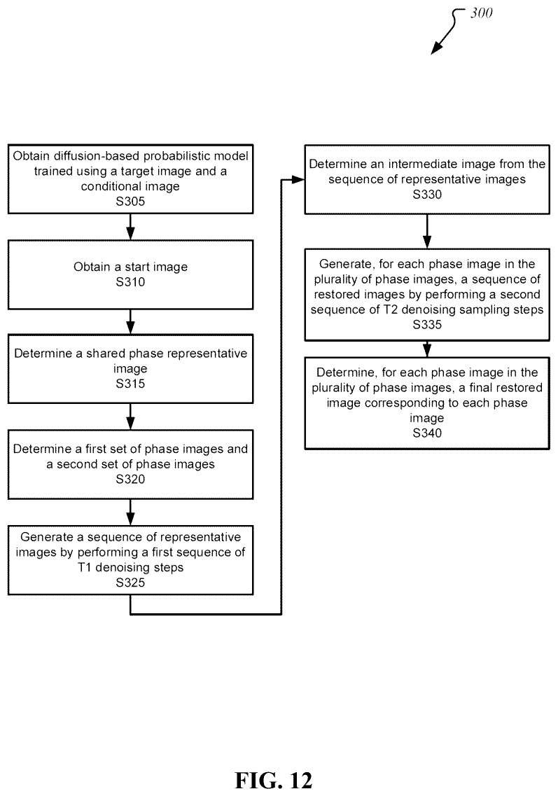

FIG. 12 shows a non-limiting example of a flow chart for a method 300 of joint multiphasic imaging diffusion-based denoising, according to one embodiment of the present disclosure. In one embodiment, a trained DDPM can be used to denoise a series of multiphasic images. The series of multiphasic images can be collected over a period of time, such as before, during, and after injection of a contrast agent in a patient.

In one embodiment, step S305 is obtaining a diffusion-based probabilistic model that was trained, using at least one target image and at least one conditional image, to perform denoising over T steps, wherein T is an integer greater than or equal to two.

In one embodiment, step S310 is obtaining a start image, which can be a pure noise image. The pure noise image x_{T} can be input to the DDPM.

In one embodiment, step S315 is determining a shared phase representative image based on a plurality of images. The plurality of images can be, for example, the series of multiphasic images.

In one embodiment, step S320 is determining a first set of phase images and a second set of phase images from the plurality of images. Additional sets of phase images can also be determined from the plurality of images. In one embodiment, determining the first set of phase images and the second set of phase images from the plurality of images further comprises determining a first set of the plurality of images within a first time frame includes a first level of contrast agent below a first threshold value and determining a second set of the plurality of images within a second time frame includes a second level of contrast agent at or above the first threshold value.

In one embodiment, step S325 is generating a sequence of representative images by performing a first sequence of T1 denoising sampling steps using the obtained model starting with the start image and the shared phase representative image as initial first sequence inputs. A representative image, such as the shared phase representative image, can be input as a conditional image (y) to the DDPM. The shared phase representative image can be, for example, an average of the plurality of images. The DDPM can denoise the pure noise (starting) image x̅_{T} based on the conditional (shared phase representative) image in a series of T1 initial diffusion steps to generate a sequence of (restored) representative images, wherein T1<T. At each diffusion step, the restored shared phase representative image from the previous diffusion step can be input to the DDPM along with the conditional image and the timestep (T−1, T−2, etc.). For example, the DDPM can denoise the pure noise image x_{T} based on the conditional image to generate the restored representative image x̅_{T-1} at time step T−1. The DDPM can then denoise the image x̅_{T-1} based on the conditional image to generate a further restored (denoised) representative image x̅_{T-2} at time step T−2.

In one embodiment, step S330 is determining, from the sequence of representative images, an intermediate image. After T1 diffusion steps, the DDPM can output a (restored) intermediate image x̅ₜ that has been generated using the shared phase representative image as the conditional image. The intermediate image x̅ₜ can be a last image of the sequence of representative images generated by the DDPM in the T1 diffusion steps.

In one embodiment, step S335 is for each phase image in each set of phase images, generating a corresponding sequence of restored images by performing a second sequence of T2 denoising sampling steps using the obtained model with the intermediate image and the input image as initial second sequence inputs. The DDPM can then be used to denoise the intermediate image xₜ using each of the images in each set of the one or more sets of phase images. For example, the DDPM can denoise the intermediate image xₜ using the images from the set of non-contrast phase images as the conditional images in a series of subsequent diffusion steps to output a final restored image x₀ corresponding to the original image.

In one embodiment, step S340 is for each phase image in each set of phase images, determining a corresponding final restored image for each phase image based on the generated corresponding sequence of restored images. The DDPM can denoise the intermediate image xₜ using a first non-contrast phase image in the first set of phase images as the conditional image in a series of subsequent diffusion steps to output a first final restored image corresponding to the original first non-contrast phase image in the first set of phase images. The DDPM can denoise the intermediate image xₜ using a second non-contrast phase image as the conditional image in a series of subsequent diffusion steps to output a second final restored image corresponding to the original second non-contrast phase image in the first set of phase images, etc. In one embodiment, the DDPM can denoise the intermediate image xₜ in t subsequent diffusion steps, wherein t+T1=T total diffusion steps. The t subsequent diffusion steps can be referred to herein with the quantity T2. In this manner, the DDPM can denoise each image in a series N of multiphasic images using T1+(T2*N) diffusion steps, wherein T1+T2=T. This method reduces the number of diffusion steps needed in comparison with the method illustrated in FIG. 10A, which uses N*T steps to diffuse a series of N images.

The process of generating the intermediate image for a series of multiphasic images and denoising the intermediate image conditioned on each image in the set of phase images can be repeated for each set of the one or more sets of phase images. Each set of the one or more sets of phase images can include the same or a different number of images. The number of initial diffusion steps T1 and the number of subsequent diffusion steps T2 can vary for each set of the one or more sets of phase images or can be the same for each set of the one or more sets of phase images. In one embodiment, the number of initial diffusion steps T1 can be referred to as a length of the initial diffusion process using the shared phase representative images. The length of the initial diffusion process can be modulated based on the expected content of the images in the set of phase images. For example, the length of the initial diffusion process can be modulated based on an expected size of one or more features. In one embodiment, the length of the initial diffusion process and/or the number of total diffusion steps (T) can be dependent on the training of the DDPM.

In one embodiment, an image can be downsampled prior to a diffusion step. For example, the shared phase representative image of a set of phase images can be downsampled prior to initial diffusion steps so that the downsampled shared phase representative image is smaller in size than the original images of the set of phase images. Downsampling the shared phase representative image can reduce the processing time or capacity needed to denoise the shared phase representative image in the initial diffusion steps. The shared phase representative image can be downsampled without affecting the appearance of features that are identified (denoised) in the initial diffusion steps.

In one embodiment, the final intermediate image x̅ₜ that is generated after T1 initial diffusion steps can be upsampled prior to the remaining T2 diffusion steps that are conditioned on the individual images in the set of phase images. The upsampling can resize the intermediate image x̅ₜ so that the image x̅ₜ is the same size as any of the original images of the set of phase images. The upsampling can restore image data that is needed for denoising of smaller details in the images.

In one embodiment, various parameters can be modulated for the method 300. The parameters can be shared between the sets of phase images or can be different for one or more sets of phase images. In one embodiment, the shared phase representative image (conditional image (y)) can vary and impact an image quality of the final restored image(s). In one embodiment, the initial shared sampling step (T−t) can determine how many sampling steps are recovered with the shared conditional image. The more numerous the shared sampling steps, the faster the method 300 will process or complete. In one embodiment, the shared sampling step for each set of phase images (T−tₐ, T−t_{b}, etc. where a and b denote a determined, separate phase) can be different for different following restoration phases depending on a level of anatomical differences between the conditional image and the intermediate image. In one embodiment, a look-up-table (LUT) can be used to determine how many sampling steps can be recovered by providing recommended or predicted optimal shared conditional images based on any one of historical scan and image reconstruction data, scan parameters, patient data, contrast agent parameters, etc. In one embodiment, the shared conditional image can be selected by an operator. In one embodiment, a combination of the LUT and the manual operator selection can be used to determine the shared conditional image. In one embodiment, the shared conditional image can automatically be determined by processing circuitry. The processing circuitry can determine an image difference for a last image in the sequence of representative images compared to a first image in the first set of phase images and a first image in the second set of phase images is greater than a predetermined threshold and select a preceding image preceding the last image in the sequence of representative images.

By taking advantage of similar anatomical structure between phases, and assuming the noisy (early sampling step), low-detail intermediate image of multiphasic images would be very similar, significant processing time can be saved without much cost in image quality when using an appropriate conditional image and shared sampling step.

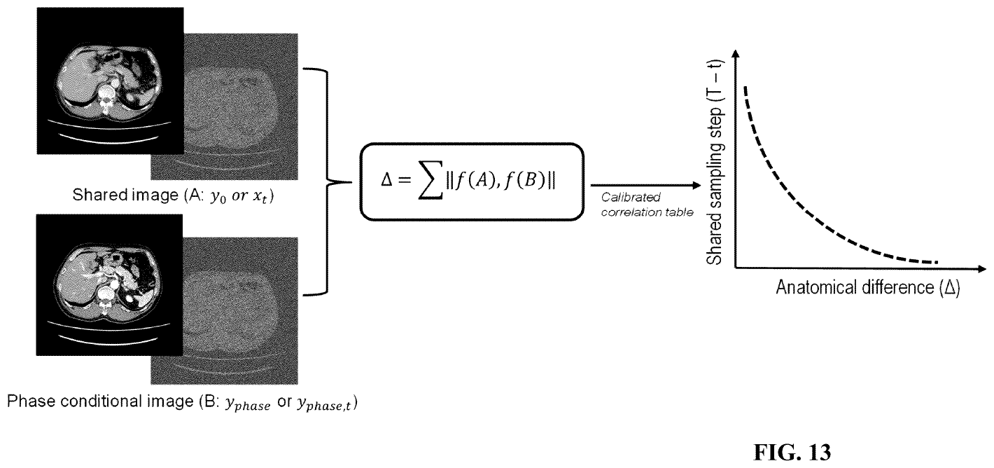

FIG. 13 is a schematic of automatically determining the shared sampling step number, according to one embodiment of the present disclosure. In one embodiment, the shared sampling step (T−t) and its variational form (tₐ, t_{b}, . . . ) for each phasic image is essential for balancing output image quality and processing time. Therefore, a new method for automatically selecting the shared sampling step number in the processing workflow can be very helpful since the early sampling step in the diffusion inference process is more related to low-frequency features (e.g., shape & different anatomical segment). A feature difference measurement between the shared conditional image (y) or intermediate image (xₜ) to the following phase condition image (yₚₕₐₛₑ, or simulated conditional image in intermediate noise state y_{phase,t}) can be used to determine the length of t. The difference function (f) can be, for example, a low pass filter.

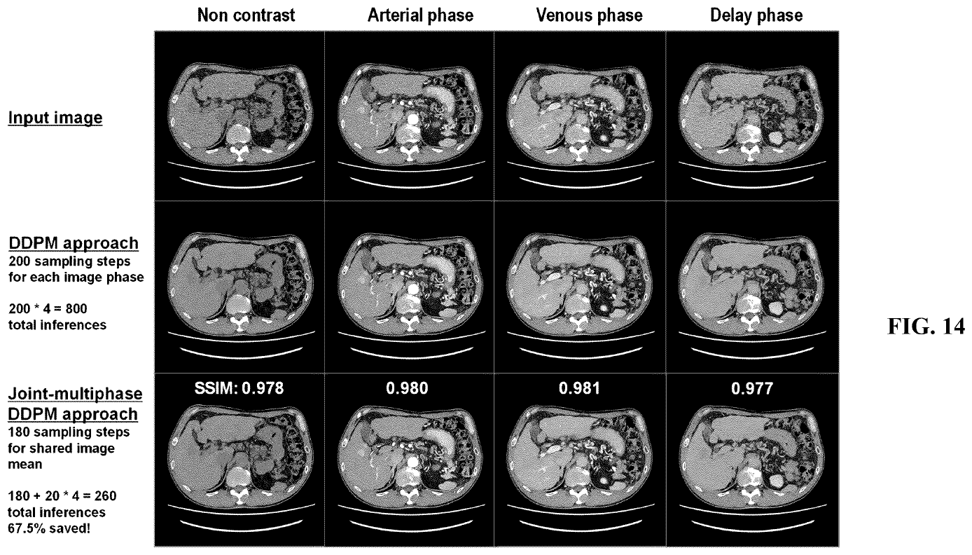

FIG. 14 illustrates the results of the joint multiphasic imaging diffusion-based denoising, according to one embodiment of the present disclosure. In one embodiment, FIG. 14 is an illustration of various input images during imaging of an injected contrast agent that are divided into four sets of phase images (top row). The DDPM can denoise each set of phase images. The series of images can be denoised by the DDPM using 200 diffusion or samplings steps for each image, resulting in 800 total diffusion steps or inferences (middle row). The series of images can be denoised by the DDPM using the joint multiphasic imaging diffusion-based denoising, wherein T1=180 and T2=20. Therefore, the series of multiphasic images can be denoised using 190+(20*4)=260 diffusion steps, resulting in a 67.5% reduction in processing. The denoised images of the middle row of FIG. 14 using the DDPM approach and the top row of FIG. 14 using the joint multiphasic imaging diffusion-based denoising have the same quality and level of recovery as indicated by the structural similarity index measure (SSIM) values listed that are greater than 0.95. Of course, the values for T1 and T2 can be adjusted to increase or decrease the processing used based on the output image quality.

The systems and methods described herein are compatible with other methods for reducing the processing time of a diffusion-based image denoising model. Such methods can include, but are not limited to, using a denoising diffusion implicit model; reducing the number of diffusion steps T; implementing an early stop to the diffusion process; using a fast ordinary differential equation solver; pre-segmentation diffusion sampling; and using a high-frequency space diffusion model.

Embodiments of the present disclosure may also be as set forth in the following parentheticals.

(1) A method of denoising images, including obtaining a diffusion-based probabilistic model that was trained, using at least one target image and at least one conditional image, to perform denoising over T steps, wherein T is an integer greater than or equal to two; obtaining a start image; determining a shared phase representative image based on a plurality of phase images; generating a sequence of representative images by performing a first sequence of T1 denoising sampling steps using the obtained model starting with the start image and the shared phase representative image as initial first sequence inputs; determining, from the generated sequence of representative images, an intermediate image; and for each phase image in the plurality of phase images: generating a corresponding sequence of restored images by performing a second sequence of T2 denoising sampling steps using the obtained model with the intermediate image and the input image as initial second sequence inputs; and determining a corresponding final restored image for each phase image based on the generated corresponding sequence of restored images, wherein T1 and T2 are integers greater than or equal to 1.

(2) The method of (1), wherein T1 is greater than T2.

(3) The method of (1), wherein T1 is less than T2.

(4) The method of any one of (1) to (3), wherein the step of generating the corresponding sequence of restored images comprises, for each sampling step in the sequence, supplying, as input to the obtained model, a preceding one of the sequence of restored images for phase image, and a value indicating the sampling step.

(5) The method of any one of (1) to (4), wherein the determining the intermediate image further comprises: determining an image difference for a last image in the sequence of representative images compared to a first image in a first set of phase images and a first image in a second set of phase images is greater than a predetermined threshold; and selecting a preceding image preceding the last image in the sequence of representative images.

(6) The method of any one of (1) to (5), further comprising determining the first set of phase images and the second set of phase images from the plurality of phase images by: determining a first set of the plurality of phase images within a first time frame includes a first level of contrast agent below a first threshold value; and determining a second set of the plurality of phase images within a second time frame includes a second level of contrast agent at or above the first threshold value.

(7) The method of any one of (1) to (6), wherein the step of determining the shared phase representative image comprises determining an average of each image of the plurality of phase images.

(8) The method of any one of (1) to (7), further comprising obtaining the plurality of phase images as a time sequence of reconstructed medical images.

(9) The method of any one of (1) to (8), further comprising determining the number T1 of denoising sampling steps for the generating of the sequence of representative images via a look-up table.

(10) The method of any one of (1) to (9), further comprising determining the number T1 of denoising sampling steps for the generating of the sequence of representative images via a manual input from an operator.

(11) a non-transitory computer-readable storage medium for storing computer readable instructions that, when executed by a computer, cause the computer to perform a method, the method including obtaining a diffusion-based probabilistic model that was trained, using at least one target image and at least one conditional image, to perform denoising over T steps, wherein T is an integer greater than or equal to two; obtaining a start image; determining a shared phase representative image based on a plurality of phase images; generating a sequence of representative images by performing a first sequence of T1 denoising sampling steps using the obtained model starting with the start image and the shared phase representative image as initial first sequence inputs; determining, from the generated sequence of representative images, an intermediate image; and for each phase image in the plurality of phase images: generating a corresponding sequence of restored images by performing a second sequence of T2 denoising sampling steps using the obtained model with the intermediate image and the input image as initial second sequence inputs; and determining a corresponding final restored image for each phase image based on the generated corresponding sequence of restored images, wherein T1 and T2 are integers greater than or equal to 1.

(12) The apparatus of (11), wherein T1 is greater than T2.

(13) The apparatus of (11), wherein T1 is less than T2.

(14) The apparatus of any one of (11) to (13), wherein the processing circuitry is further configured to generate the corresponding sequence of restored images by for each sampling step in the sequence, supplying, as input to the obtained model, a preceding one of the sequence of restored images for the phase image, and a value indicating the sampling step.

(15) The apparatus of any one of (11) to (14), wherein the processing circuitry is further configured to determine the intermediate image by determining an image difference for a last image in the sequence of representative images compared to a first image in a first set of phase images and a first image in a second set of phase images is greater than a predetermined threshold, and selecting a preceding image preceding the last image in the sequence of representative images.

(16) The apparatus of any one of (11) to (15), wherein the processing circuitry is further configured to determine the first set of phase images and the second set of phase images from the plurality of phase images by: determining a first set of the plurality of phase images within a first time frame includes a first level of contrast agent below a first threshold value; and determining a second set of the plurality of phase images within a second time frame includes a second level of contrast agent at or above the first threshold value.

(17) The apparatus of any one of (11) to (16), wherein the processing circuitry is further configured to determine the shared phase representative image by calculating an average of the plurality of phase images.

(18) The apparatus of any one of (11) to (17), wherein the processing circuitry is further configured to obtain the plurality of phase images as a time sequence of reconstructed medical images.

(19) The apparatus of any one of (11) to (18), wherein the processing circuitry is further configured to determine the number T1 of denoising sampling steps for the generating of the sequence of representative images via a look up table.

(20) An apparatus, comprising processing circuitry configured to obtain a diffusion-based probabilistic model that was trained, using at least one target image and at least one conditional image, to perform denoising over T steps, wherein T is an integer greater than or equal to two; obtain a start image; determine a shared phase representative image based on a plurality of phase images; generate a corresponding sequence of representative images by performing a first sequence of T1 denoising sampling steps using the obtained model starting with the start image and the shared phase representative image as initial first sequence inputs; determine, from the generated sequence of representative images, an intermediate image; and for each phase image in the plurality of phase images: generate a corresponding sequence of restored images by performing a second sequence of T2 denoising sampling steps using the obtained model with the intermediate image and the input image as initial second sequence inputs; and determine a final restored image for each phase image based on the generated corresponding sequence of restored images, wherein T1 and T2 are integers greater than or equal to 1.

Obviously, numerous modifications and variations are possible in light of the above teachings. It is therefore to be understood that within the scope of the appended claims, embodiment of the present disclosure may be practiced otherwise than as specifically described herein.

1. A method of denoising images, the method comprising:
obtaining a diffusion-based probabilistic model that was trained, using at least one target image and at least one conditional image, to perform denoising over T steps, wherein T is an integer greater than or equal to two;
obtaining a start image;
determining a shared phase representative image based on a plurality of phase images;
generating a sequence of representative images by performing a first sequence of T1 denoising sampling steps using the obtained model starting with the start image and the determined shared phase representative image as initial first sequence inputs;
determining, from the generated sequence of representative images, an intermediate image; and
for each phase image in the plurality of phase images:
generating a corresponding sequence of restored images by performing a second sequence of T2 denoising sampling steps using the obtained model with the intermediate image and the phase image as initial second sequence inputs; and
determining a corresponding final restored image for each phase image based on the generated corresponding sequence of restored images,
wherein T1 and T2 are integers greater than or equal to 1.

2. The method of claim 1, wherein T1 is greater than T2.

3. The method of claim 1, wherein T1 is less than T2.

4. The method of claim 1, wherein the step of generating the corresponding sequence of restored images comprises, for each sampling step in the sequence, supplying, as input to the obtained model, a preceding one of the sequence of restored images for phase image, and a value indicating the sampling step.

5. The method of claim 1, wherein the determining the intermediate image further comprises:
determining an image difference for a last image in the sequence of representative images compared to a first image in a first set of phase images and a first image in a second set of phase images is greater than a predetermined threshold; and
selecting a preceding image preceding the last image in the sequence of representative images.

6. The method of claim 5, further comprising determining the first set of phase images and the second set of phase images from the plurality of phase images by:
determining a first set of the plurality of phase images within a first time frame includes a first level of contrast agent below a first threshold value; and
determining a second set of the plurality of phase images within a second time frame includes a second level of contrast agent at or above the first threshold value.

7. The method of claim 1, wherein the step of determining the shared phase representative image comprises determining an average of each image of the plurality of phase images.

8. The method of claim 1, further comprising obtaining the plurality of phase images as a time sequence of reconstructed medical images.

9. The method of claim 1, further comprising determining the number T1 of denoising sampling steps for the generating of the sequence of representative images via a look-up table.

10. The method of claim 1, further comprising determining the number T1 of denoising sampling steps for the generating of the sequence of representative images via a manual input from an operator.

11. A method for performing diffusion-based image processing on a plurality of input images, the method comprising:
obtaining a diffusion-based probabilistic model (DDPM) that was trained to restore a target image from noise over T sampling steps, wherein T is an integer greater than or equal to 3;
dividing the T sampling steps into M tiers, wherein M is an integer greater than or equal to 3; and
processing the plurality of input images in a tier-by-tier manner using the obtained DDPM, to generate a plurality of processed images,
wherein in each tier of a first M−1 tiers, the processing further comprises:
grouping the plurality of input images into one or more groups, and
over a sampling step within the tier, for each group of the one or more groups, performing shared diffusion-based image processing on a representative image of the group, so as to generate a representative intermediate image, which is used as a starting point for the diffusion-based image processing in a subsequent tier, and
wherein in a last tier of the M tiers, the processing further comprises:
over a sampling step within the last tier, performing diffusion-based image processing independently with respect to each image of the plurality of input images, without sharing.

12. The method of claim 11, further comprising, within the first M−1 tiers, grouping the plurality of input images into fewer groups in a preceding tier than in a following tier.

13. The method of claim 11, wherein within the M tiers, a preceding tier spans either a greater number of sampling steps or a same number of sampling steps as a following tier.

14. The method of claim 11, further comprising, in a first tier of the M tiers, grouping the plurality of input images into a single group, and the representative image of the single group is:
generated as an average of the plurality of input images, or
selected, from the plurality of input images, as an image that contains more structural features or exhibits a better image quality than other images among the plurality of input images.

15. The method of claim 11, wherein the plurality of input images comprise a series of continuous images.

16. The method of claim 15, wherein the series of continuous images comprise a series of images acquired sequentially over a spatial direction.

17. The method of claim 15, wherein the series of continuous images comprise a series of images acquired sequentially over a temporal direction.

18. The method of claim 15, wherein the series of continuous images comprise a series of images aligned through an image registration procedure.

19. The method of claim 11, further comprising inputting a conditional image into the obtained DDPM to guide the diffusion-based image processing through a contextual constraint.

20. The method of claim 11, further comprising acquiring the plurality of input images from a scan performed using a medical imaging system on an imaging object.
